(19) United States
(12) Patent Application Publication
(10) Pub. No.: US 2026/0321552 A1
(43) Pub. Date: Oct. 15, 2026

(54) MOVEABLE EDGE RINGS FOR PLASMA PROCESSING SYSTEMS

(71) Applicant: LAM RESEACH CORPORATION, Fremont, CA (US)

(72) Inventors: Christopher KIMBALL, San Jose, CA (US); Darrell EHRLICH, San Jose, CA (US); Yuma OHKURA, San Mateo, CA (US)

(21) Appl. No.: 19/462,958

(22) Filed: Jan. 28, 2026

Related U.S. Application Data
(63) Continuation of application No. 18/029,708, filed on Sep. 29, 2021, now Pat. No. 12,562,350.
(60) Provisional application No. 63/087,814, filed on Oct. 5, 2020.

(51) Int. Cl. H01J 37/32; H10P 72/76

(52) U.S. Cl. CPC H01J 37/32642; H01J 37/32651; H10P 72/7611; H10P 72/7612

(57) ABSTRACT

A moveable edge ring system for a substrate processing system includes a top moveable ring including a first annular body arranged around a substrate support. The top moveable ring is exposed to plasma during substrate processing. A moveable support ring is arranged below the top moveable ring and radially outside of a baseplate of the substrate support and includes a second annular body. A shield ring is arranged radially outside of the moveable support ring and includes a third annular body. A cover ring includes a fourth annular body arranged above a radially outer edge of the top moveable ring. An actuator and a lift pin are configured to adjust a position of the top moveable ring and the moveable support ring relative to the shield ring and the cover ring.

### CROSS-REFERENCE TO RELATED APPLICATIONS

This application is a continuation of U.S. Application No. 18/029,708 filed Mar. 31, 2023, which is a U.S. National Phase Application under 35 U.S.C. 371 of International Application No. PCT/US2021/052732, filed on Sep. 29, 2021, which claims the benefit of U.S. Provisional Application No. 63/087,814, filed on Oct. 5, 2020. The entire disclosures of the applications referenced above are incorporated herein by reference.

### FIELD

The present disclosure relates generally to plasma processing systems and more particularly to edge ring systems with a moveable edge ring.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems perform treatments on substrates such as semiconductor wafers. Examples of substrate treatments include deposition, ashing, etching, cleaning and/or other processes. Process gas mixtures may be supplied to the processing chamber to treat the substrate. Plasma may be used to ignite the gases to enhance chemical reactions.

A substrate is arranged on a substrate support during treatment. An edge ring has an annular body that is arranged around and adjacent to a radially outer edge of the substrate. The edge ring may be used to shape or focus the plasma onto the substrate. During operation, the substrate and an exposed surface of the edge ring is etched by the plasma. As a result, the edge ring wears and the effect of the edge ring on the plasma changes, which may adversely affect uniformity.

### SUMMARY

A moveable edge ring system for a substrate processing system includes a top moveable ring including a first annular body arranged around a substrate support. The top moveable ring is exposed to plasma during substrate processing. A moveable support ring is arranged below the top moveable ring and radially outside of a baseplate of the substrate support and includes a second annular body. A shield ring is arranged radially outside of the moveable support ring and includes a third annular body. A cover ring includes a fourth annular body arranged above a radially outer edge of the top moveable ring. An actuator and a lift pin are configured to adjust a position of the top moveable ring and the moveable support ring relative to the shield ring and the cover ring.

In other features, the top moveable ring includes a first annular recess on an upper and radially outer surface of the first annular body. The shield ring includes a projection extending upwardly from an upper and radially outer surface of the third annular body. The cover ring includes a second annular recess configured to receive the projection. A third annular recess is configured to align with the first annular recess of the top moveable ring when the top moveable ring and the moveable support ring are raised.

In other features, the top moveable ring, the moveable support ring, and the shield ring are conductive while the cover ring is nonconductive. As the top moveable ring and the moveable support ring are moved from a lowest position to intermediate positions and to an uppermost position, the moveable support ring maintains greater than or equal to about 70% of vertical side portions of a radially outer surface of the moveable support ring within a predetermined coupling gap of the shield ring and greater than or equal to about 50% of vertical side portions of a radially inner surface of the moveable support ring are located within a predetermined coupling gap of the baseplate. In some embodiments, the predetermined coupling gap is greater than zero and less than or equal to about 20 mils.

In other features, as the top moveable ring and the moveable support ring are moved from a lowest position to intermediate positions and to an uppermost position, the moveable support ring maintains greater than or equal to about 90% of vertical side portions of a radially outer surface of the moveable support ring within a predetermined coupling gap of the shield ring and greater than or equal to about 60% of vertical side portions of a radially inner surface of the moveable support ring are located within a predetermined coupling gap of the baseplate. In some embodiments, the predetermined coupling gap is greater than zero and less than or equal to about 20 mils.

In other features, an edge ring including a fifth annular body having an “L”-shaped cross-section. The substrate support includes a heating layer arranged on a baseplate. The edge ring is arranged between the heating layer of the substrate support and radially inner sides of the top moveable ring and the moveable support ring.

In other features, the top moveable ring, the moveable support ring and the shield ring are conductive, and the cover ring and the edge ring are nonconductive. An edge ring includes a fifth annular body and is arranged radially outside of the shield ring and the cover ring. The top moveable ring, the moveable support ring and the shield ring are conductive, and the cover ring and the edge ring are nonconductive.

In other features, the edge ring includes an annular recess on an upper and radially inner surface thereof to receive the cover ring. A lower surface of the moveable support ring includes a ring centering portion to center the moveable support ring when the lift pin biases the ring centering portion. A lower surface of the top moveable ring includes a ring centering portion to center the top moveable ring when the moveable support ring biases the ring centering portion of the top moveable ring.

In other features, at least one of the top moveable ring, the moveable support ring and the shield ring includes a horizontal ring spacer. The horizontal ring spacer includes at least one of a shim, a projection and a pin.

A system includes the moveable edge ring system and the substrate support configured to support a substrate. A controller is configured to control the actuator to move the lift pin to adjust a height of the moveable support ring and the top moveable ring relative to the substrate support.

In other features, the controller is configured to adjust the height of the moveable support ring and the top moveable ring in response to at least one of a number of RF plasma cycles, a number of substrates processed and a period of a RF exposure.

An edge ring system for a substrate processing system includes a top stationary ring including a first annular body that is directly exposed to plasma during substrate processing. A moveable ring is arranged below the top stationary ring and radially outside of a baseplate of a substrate support and including a second annular body. A shield ring is arranged below and radially outside of the moveable ring and including a third annular body. An actuator and lift pin are configured to adjust a position of the moveable ring relative to the top stationary ring and the shield ring.

In other features, a cover ring is nonconductive and is arranged above a radially outer edge of the top stationary ring. The top stationary ring includes a first annular recess on an upper and radially outer surface of the first annular body.

In other features, the shield ring includes a projection extending upwardly from an upper and radially outer surface of the third annular body. The cover ring includes a second annular recess configured to receive the projection and a third annular recess configured to mate with the first annular recess of the top stationary ring.

In other features, the top stationary ring, the moveable ring and the shield ring are made of conductive material. As the moveable ring is moved from a lowest position to intermediate positions and to an uppermost position, the moveable ring maintains greater than or equal to about 70% of vertical side portions of a radially outer surface of the moveable ring within a predetermined coupling gap of the shield ring and greater than or equal to about 50% of vertical side portions of a radially inner surface of the moveable ring within a predetermined coupling gap of the baseplate. The predetermined coupling gap is less than or equal to about 30 mils.

In other features, the moveable ring has a “T”-shaped cross-section and the shield ring has an inverted “T”-shaped cross-section. A cover ring includes a fourth annular body. A substrate support includes a heating layer arranged on a baseplate, and wherein the cover ring is arranged between the heating layer of the substrate support and a radially inner surface of the top stationary ring when the top stationary ring is in a lowered position.

In other features, the top stationary ring, the moveable ring and the shield ring are conductive, and the cover ring is nonconductive.

In other features, an edge ring includes an annular body and arranged radially outside of the shield ring.

In other features, the edge ring includes an annular recess on an upper and radially inner surface thereof to receive the cover ring. The top stationary ring, the moveable ring and the shield ring are conductive, and the cover ring and the edge ring are nonconductive.

In other features, the top stationary ring includes a radially inner portion, an upwardly sloped portion extending from the radially inner portion, a planar portion extending from the upwardly sloped portion. The moveable ring includes a radially inwardly projecting portion and a radially outwardly projecting portion. An upper and radially inner surface of the radially inwardly projecting portion includes a sloped portion.

In other features, an upper surface of the sloped portion extends parallel to a lower surface of the upwardly sloped portion. A lower surface of the moveable ring includes a ring centering portion to center the moveable ring when the lift pin biases the ring centering portion of the moveable ring. At least one of the top stationary ring, the moveable ring and the shield ring includes a horizontal ring spacer.

In other features, the horizontal ring spacer includes at least one of a shim, a projection and a pin.

A system comprises the edge ring system, the substrate support configured to support a substrate and a controller configured to adjust a height of the actuator to move the lift pin to adjust a height of the moveable ring relative to the top stationary ring.

In other features, the controller is configured to adjust the height of the moveable ring in response to at least one of a number of RF plasma cycles, a number of substrates processed and a period of a RF exposure.

A substrate processing system includes a substrate support including cylindrical body, an annular projecting portion extending from a lower portion of the cylindrical body, and a shield portion extending upwardly from a radially outer edge of the annular projecting portion, wherein a cavity is defined between the cylindrical body and the shield portion. A top moveable ring includes a first annular body arranged around a substrate support. The top moveable ring is exposed to plasma during substrate processing. A moveable support ring includes a second annular body. The moveable support ring is arranged below the top moveable ring in the cavity between the shield portion and the cylindrical body.

In other features, a cover ring is arranged above a radially outer edge of the top moveable ring. An actuator and lift pin are configured to adjust a position of the top moveable ring and the moveable support ring relative to the shield portion and the cover ring. The top moveable ring includes a first annular recess on an upper and radially outer surface of the first annular body.

In other features, the top moveable ring, the cylindrical body, the moveable support ring and the shield portion are conductive, and the cover ring is nonconductive. As the top moveable ring and the moveable support ring are moved from a lowest position to intermediate positions and to an uppermost position, the moveable support ring maintains greater than or equal to about 70% of vertical side portions of a radially inner surface of the moveable support ring within a predetermined coupling gap of the cylindrical body and greater than or equal to about 50% of vertical side portions of a radially outer surface of the moveable support ring are located within a predetermined coupling gap of the shield portion. The predetermined coupling gap is greater than zero and less than or equal to about 20 mils.

In other features, a lower surface of the moveable support ring includes a ring centering portion to center the moveable support ring relative to the cylindrical body when the lift pin biases the ring centering portion of the moveable support ring. At least one of the top moveable ring, the moveable support ring and the shield ring includes a horizontal ring spacer. In some embodiments, the horizontal ring spacer includes at least one of a shim, a projection and a pin.

In other features, the system includes an actuator, a lift pin and a controller configured to cause the actuator to move the lift pin to adjust a height of the moveable support ring and the top moveable ring relative to the substrate support.

In other features, the controller is configured to adjust the height of the moveable support ring and the top moveable ring in response to at least one of a number of RF plasma cycles, a number of substrates processed and a period of a RF exposure.

A moveable edge ring system for a substrate processing system includes a top moveable ring including a first annular body arranged around a substrate support. An upper surface of the top moveable ring is exposed to plasma during substrate processing. A moveable support ring is arranged below the top moveable ring and radially outside of a baseplate of the substrate support and includes a second annular body. A shield ring is arranged below and radially outside of the moveable support ring and includes a third annular body. An actuator and a lift pin configured to adjust a position of the top moveable ring and the moveable support ring relative to the shield ring. The top moveable ring, the moveable support ring and the shield ring are made of conductive material. As the top moveable ring and the moveable support ring are moved from a lowest position to intermediate positions and to an uppermost position, the moveable support ring maintains greater than or equal to about 70% of vertical side portions of a radially outer surface of the moveable support ring within a predetermined coupling gap of the shield ring and greater than or equal to about 50% of vertical side portions of a radially inner surface of the moveable support ring within a predetermined coupling gap of the baseplate. The predetermined coupling gap is greater than zero and less than or equal to about 20 mils.

In other features, the predetermined coupling gap is greater than zero and less than or equal to about 10 mils.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a plasma processing system for substrates according to the present disclosure;

FIGS. 2A and 2B are cross-sectional side views of an example of a top moveable ring in lowered and raised positions, respectively, according to certain embodiments of the present disclosure;

FIGS. 3A and 3B are cross-sectional side views of another example of a top moveable ring in lowered and raised positions, respectively, according to certain embodiments of the present disclosure;

FIGS. 4A and 4B are cross-sectional side views of another example of a moveable ring located below a top stationary ring and arranged in lowered and raised positions, respectively, according to certain embodiments of the present disclosure;

FIGS. 5A and 5B are cross-sectional side views of another example of a top moveable ring in lowered and raised positions, respectively, according to certain embodiments of the present disclosure;

FIGS. 6A and 6B are cross-sectional side views of another example of a top moveable ring in lowered and raised positions, respectively, according to certain embodiments of the present disclosure;

FIG. 7 is a side cross-sectional view of an edge ring system including a ring with a ring spacer including a plurality of shims according to certain embodiments of the present disclosure;

FIG. 8 is a side cross-sectional view of a ring with a ring spacer including a plurality of pins according to certain embodiments of the present disclosure;

FIG. 9A is a side cross-sectional view of a ring with a ring spacer including a plurality of projections according to certain embodiments of the present disclosure;

FIG. 9B is an enlarged side cross-sectional view of a ring with a ring spacer including a projection with a raised flat portion according to certain embodiments of the present disclosure;

FIGS. 10A and 10B are side cross-sectional views of examples of ring centering portions according to certain embodiments of the present disclosure;

FIG. 11 is a flowchart of an example of a method for adjusting a height of the edge ring according to certain embodiments of the present disclosure; and

FIG. 12 is a flowchart of an example of a method for heating one or more edge rings to reposition or center the edge rings according to certain embodiments of the present disclosure.

In the drawings, reference numbers may be reused to identify similar and/or identical elements.

### DETAILED DESCRIPTION

During substrate processing, a substrate is arranged on a pedestal such as an electrostatic chuck (ESC), process gases are supplied, and plasma is struck in the processing chamber. Exposed surfaces of components within the processing chamber experience wear due to exposure to the plasma.

For example, an edge ring is arranged around a radially outer edge of the substrate to shape the plasma. After processing substrates, the exposed surface of the edge ring may be worn down and sits at a different height relative to the substrate. As a result, the effect of the edge ring on the plasma changes, which alters the effect of the process on the substrate. Therefore, in some substrate processing systems, the processing chamber will need to be opened to replace the worn edge ring.

To reduce process changes due to edge ring wear without breaking vacuum, some processing chambers deploy adjustable edge rings. These processing chambers may increase the height of the adjustable edge ring to compensate for wear or to allow tuning for different process conditions in a recipe. This approach increases the time between edge ring replacement, which reduces replacement cost and decreases the overall down time.

As the height of the edge ring changes, capacitive coupling between the plasma, the sheath and/or capacitance delivery structures (including the edge ring) also changes. These changes in capacitive coupling can cause substrate processing non-uniformities over time. Capacitive coupling variation may also occur in response to other factors such as thermal expansion of the edge rings, erosion of gaps between adjacent rings and part-to-part variability.

In some instances, coatings, spacers and/or minimum gaps are used to minimize capacitance variation. However, these mechanisms may reduce the overall coupling capacitance, which lowers the RF voltage on the edge ring. As a result, higher geometric height would be required to achieve the desired vertical tilt.

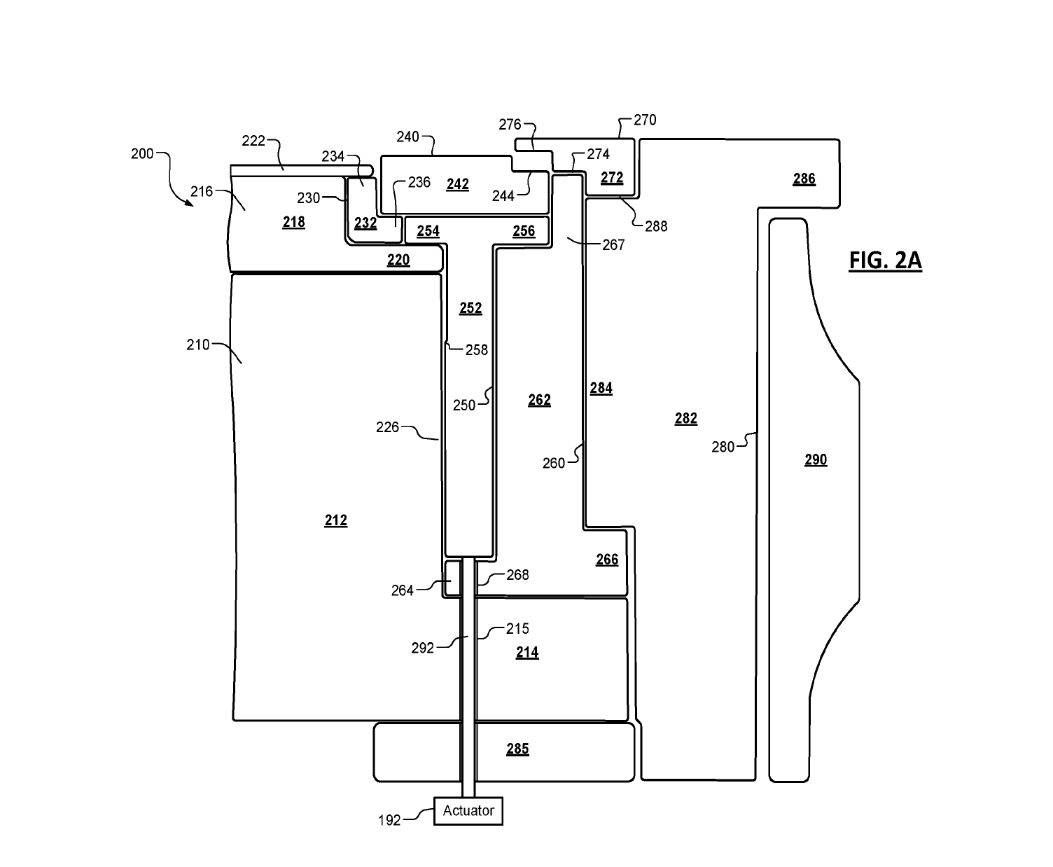

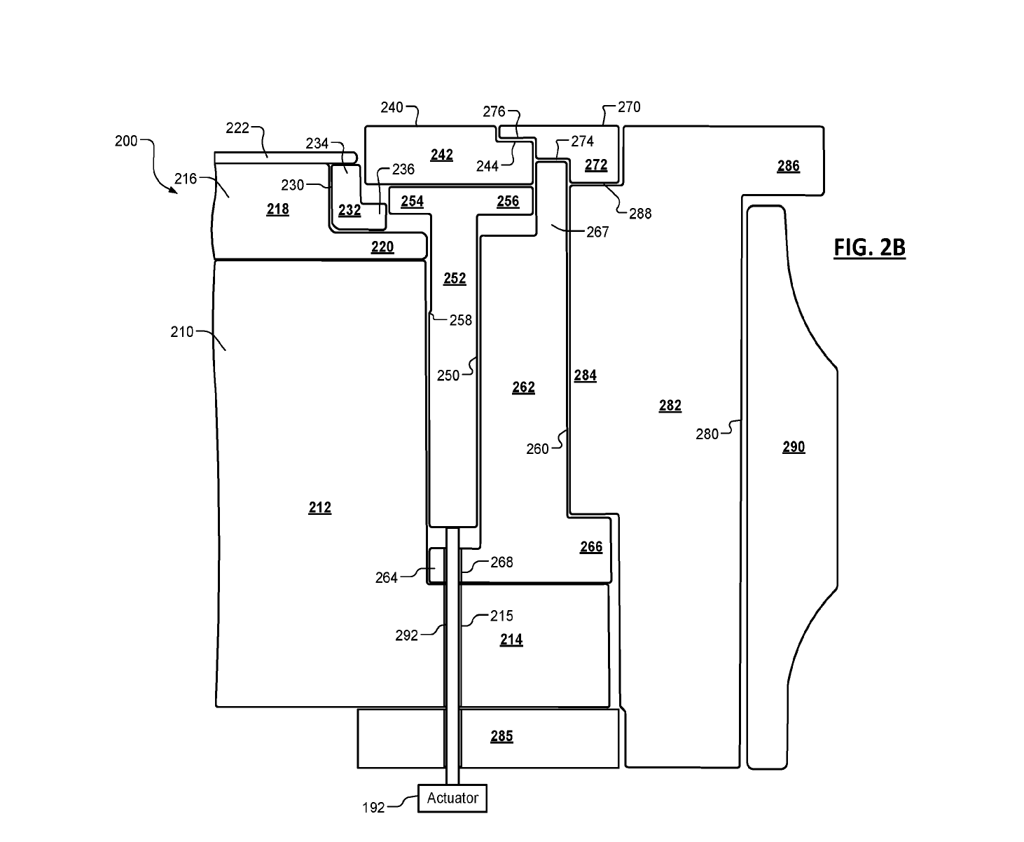

Various edge ring arrangements according to the present disclosure include a top moveable ring that reduces capacitive coupling variation as the top moveable ring is worn. FIGS. 2A and 2B, 3A and 3B, 5A and 5B and 6A and 6B illustrate tunable top moveable rings. As further described below, a geometric height of the top moveable ring can be varied by changing the height of the top moveable ring using a moveable support ring and lift pins.

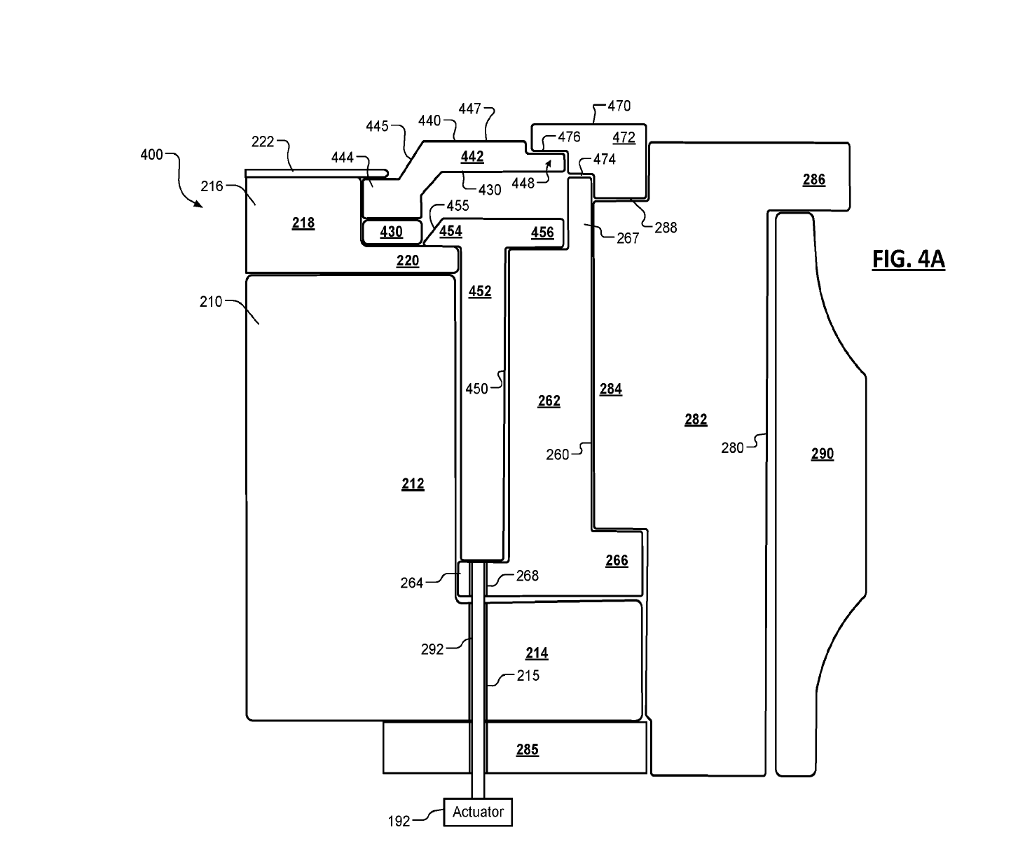

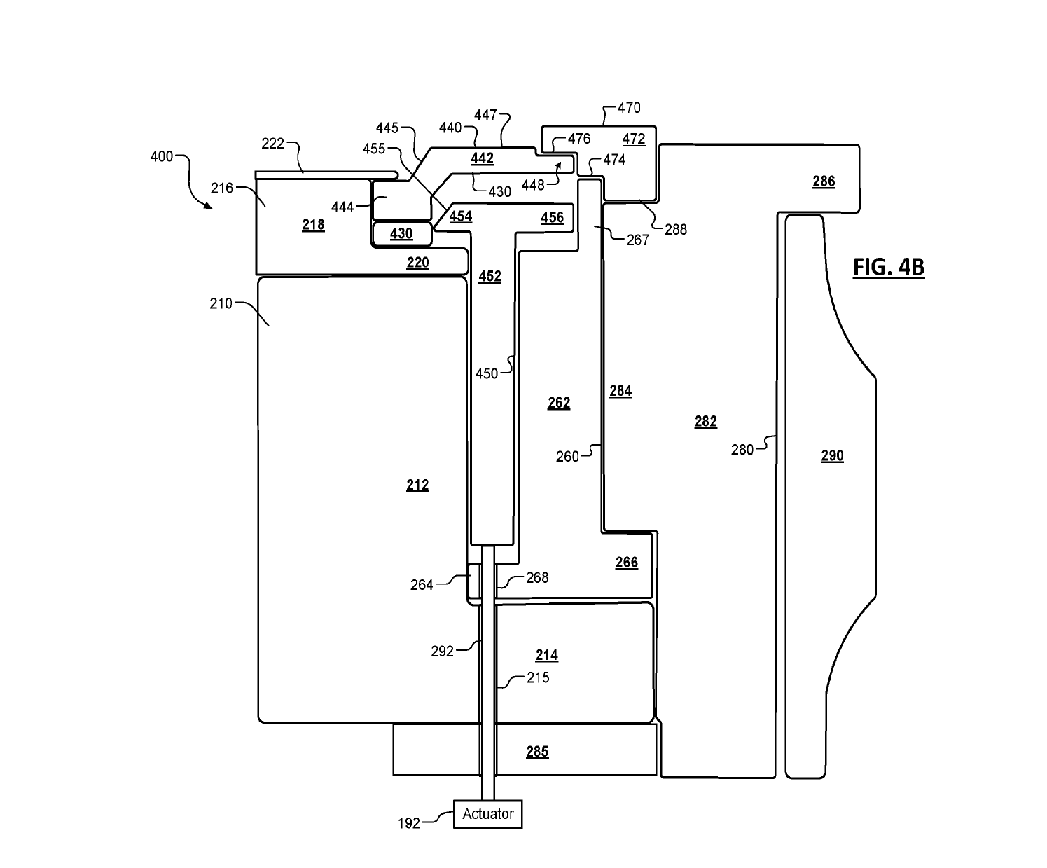

FIGS. 4A and 4B illustrate another type of tunable edge ring according to certain embodiments of the present disclosure. As described further below, a top ring in FIGS. 4A and 4B is stationary and a moveable ring and lift pin arranged below the top ring are adjusted to tune the RF voltage on the top ring and control the plasma sheath.

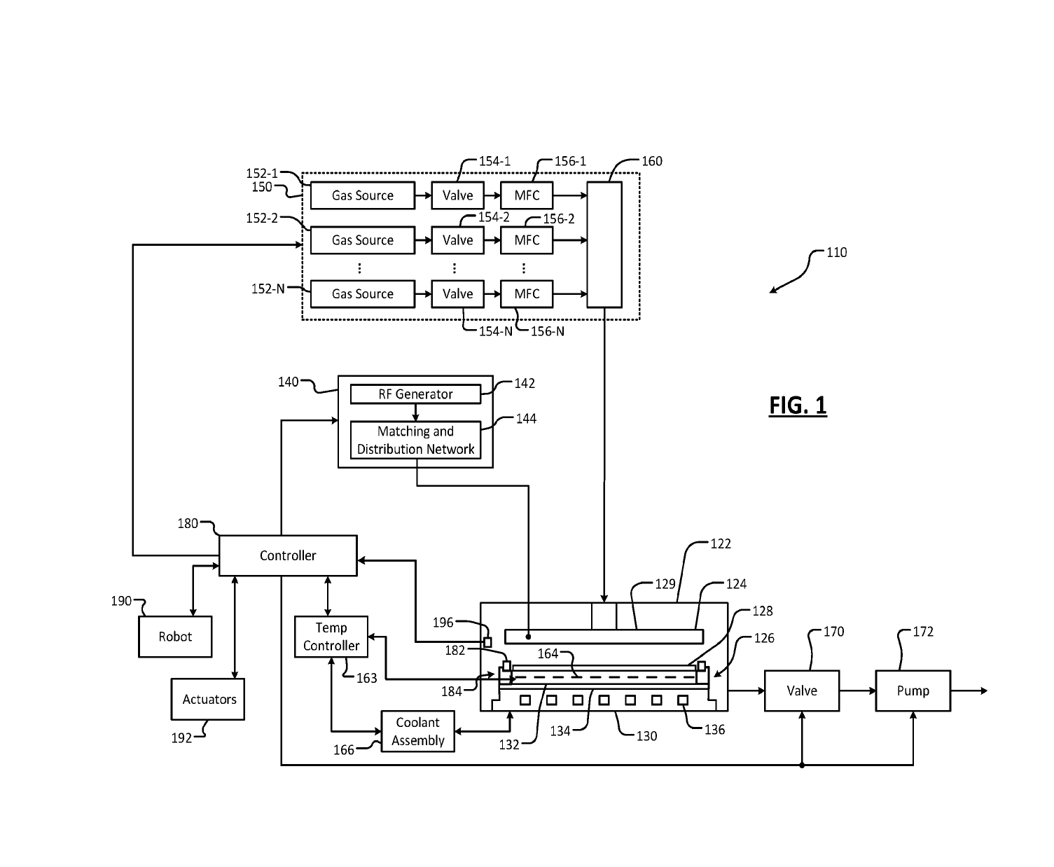

Referring now to FIG. 1, an example of a substrate processing system 110 that performs plasma processing and that includes a movable edge ring system according to certain embodiments of the present disclosure is shown. While a specific type of plasma processing chamber is shown, other plasma processing chambers can be used. The substrate processing system 110 may be used to perform etching using capacitively coupled plasma (CCP). The substrate processing system 110 includes a processing chamber 122 that encloses other components of the substrate processing system 110 and contains the RF plasma (if used). The substrate processing system 110 includes an upper electrode 124 and a substrate support 126 such as an electrostatic chuck (ESC). During operation, a substrate 128 is arranged on the substrate support 126.

For example only, the upper electrode 124 may include a gas distribution device 129 such as a showerhead that introduces and distributes process gases. The gas distribution device 129 may include a stem portion including one end connected to a top surface of the processing chamber. An annular body is generally cylindrical and extends radially outwardly from an opposite end of the stem portion at a location that is spaced from the top surface of the processing chamber. A substrate-facing surface or faceplate of the annular body of the showerhead includes a plurality of holes through which precursor, reactants, etch gases, inert gases, carrier gases, other process gases or purge gas flows. Alternately, the upper electrode 124 may include a conducting plate and the process gases may be introduced in another manner.

The substrate support 126 includes a baseplate 130 that acts as a lower electrode. The baseplate 130 supports a heating plate 132, which may correspond to a ceramic multi-zone heating plate. A bonding and/or a thermal resistance layer 134 may be arranged between the heating plate 132 and the baseplate 130. The baseplate 130 may include one or more channels 136 for flowing coolant through the baseplate 130.

An RF generating system 140 generates and outputs an RF voltage to one of the upper electrode 124 and the lower electrode (e.g., the baseplate 130 of the substrate support 126). The other one of the upper electrode 124 and the baseplate 130 may be DC grounded, AC grounded or floating. For example only, the RF generating system 140 may include an RF generator 142 that generates RF plasma power that is fed by a matching and distribution network 144 to the upper electrode 124 or the baseplate 130. In other examples, the plasma may be generated inductively or remotely.

A gas delivery system 150 includes one or more gas sources 152-1, 152-2,…, and 152-N (collectively gas sources 152), where N is an integer greater than zero. The gas sources 152 are connected by valves 154-1, 154-2, …, and 154-N (collectively valves 154) and MFCs 156-1, 156-2, …, and 156-N (collectively MFCs 156) to a manifold 160. Secondary valves may be used between the MFCs 156 and the manifold 160. While a single gas delivery system 150 is shown, two or more gas delivery systems can be used.

A temperature controller 163 may be connected to a plurality of thermal control elements (TCEs) 164 arranged in the heating plate 132. The temperature controller 163 may be used to control the plurality of TCEs 164 to control a temperature of the substrate support 126 and the substrate 128. The temperature controller 163 may communicate with a coolant assembly 166 to control coolant flow through the channels 136. For example, the coolant assembly 166 may include a coolant pump, a reservoir and/or one or more temperature sensors. The temperature controller 163 operates the coolant assembly 166 to selectively flow the coolant through the channels 136 to cool the substrate support 126.

A valve 170 and pump 172 may be used to evacuate reactants from the processing chamber 122. A system controller 180 may include one or more controllers that are used to control components of the substrate processing system 110. In some examples, a moveable edge ring 182 is arranged radially outside of the substrate 128 during plasma processing and is exposed to plasma. In other examples, a moveable edge ring is located below a stationary edge ring that is exposed to plasma. An edge ring height adjustment system 184 may be used to adjust a height of a top surface of the moveable edge ring 182 relative to the substrate 128 (or to alter the RF voltage of the stationary edge ring) as will be described further below. In some examples, the moveable edge ring 182 can also be raised, removed by a robot end effector and replaced with another edge ring without breaking vacuum.

In certain embodiments, the system controller 180 controls a robot 190 to deliver substrates and/or edge rings to the processing chamber as will be described further below. The system controller 180 also controls one or more actuators 192 that move lift pins to adjust a height or tilt of the edge rings as further described below. The system controller 180 may also receive outputs from one or more sensors 196 that are used to sense a height of the edge rings. Non-limiting examples of sensors include optical sensors, physical sensors, piezo sensors, ultrasonic sensors, etc.

Referring now to FIGS. 2A and 2B, an edge ring system 200 according to certain embodiments of the present disclosure is shown with moveable edge rings in a lowered position (FIG. 2A) and a raised position (FIG. 2B). The edge ring system 200 is configured to adjust a geometric height of an upper surface of a top moveable ring 240 relative to an upper surface of a substrate 222. The substrate support includes a baseplate 210 including a cylindrical body 212 and an annular projecting portion 214 extending radially outwardly from a lower portion of the cylindrical body 212. The annular projecting portion 214 of the baseplate 210 includes a cavity 215 extending in a vertical direction to allow a lift pin 292 to move reciprocally therein.

A heating layer 216 is arranged above the baseplate 210. The heating layer 216 includes a cylindrical body 218 and an annular projecting portion 220 extending outwardly from a lower portion of the cylindrical body 218. A bonding layer (not shown) may be arranged between the heating layer 216 and the baseplate 210

As shown in FIG. 2A, the edge ring system 200 includes a ring 230, a shield ring 260, a cover ring 270, a ring 280 and a ring 290 that are stationary, the top moveable ring 240 and a moveable support ring 250. In this context, the term stationary means that the edge rings are not generally moved after installation without breaking vacuum and the term moveable means that a position of the rings can be adjusted after installation without breaking vacuum by an actuator described further below.

The ring 230 is arranged below a radially outer edge of a substrate 222, above the annular projecting portion 220 of the heating layer 216, and between the heating layer 216 and radially inner edges of the top moveable ring 240 and the moveable support ring 250. The ring 230, according to certain embodiments, has an “L”-shaped cross section and includes an annular body 232, a vertical portion 234 and a horizontal portion 236.

The top moveable ring 240 includes an upper surface that is exposed directly to plasma. In some embodiments, the top moveable ring 240 is arranged radially outward from the substrate 222, partially below the top cover ring 270, above and adjacent to the rings 230 and 260, and directly above and in contact with moveable support ring 250. According to some embodiments, the top moveable ring 240 includes an annular body 242 having a generally rectangular cross-section and an annular recess 244 located on a radially outer and upper portion of the annular body 242.

The moveable support ring 250 includes an annular body 252 that is located below the top moveable ring 240 and between a radially inner surface of the shield ring 260 and a radially outer side surface of the baseplate 210. In some embodiments, the moveable support ring 250 has a “T”-shaped cross-section, although other cross-sections may be used. An upper portion of the moveable support ring 250 includes a radially inwardly projecting portion 254 and a radially outwardly projecting portion 256. Upper surfaces of the radially inwardly projecting portion 254 and the radially outwardly projecting portion 256 are arranged directly adjacent to and in contact with a lower surface of the top moveable ring 240.

In some embodiments, the moveable support ring 250 further includes a projecting portion 258 located along a radially inner and lower side portion of the annular body 252 to enhance coupling with the baseplate 210. In certain embodiments, the projecting portion 258 extends vertically to a location of the moveable support ring 250 that lies adjacent to the radially outer surface of the baseplate within the coupling gap for all vertical positions of the moveable support ring 250 to maintain uniform capacitive coupling.

The upper surface of the top moveable ring 240 may erode due to plasma exposure. In some embodiments, the top moveable ring 240 and the moveable support ring 250 are raised to compensate for the erosion of the upper surface such that the upper surface of the top moveable ring 240 remains in a substantially stationary position relative to substrate 222.

The shield ring 260 is located between the moveable support ring 250 and the ring 280 and above the annular projecting portion 214 of the baseplate 210. In some examples, the shield ring 260 is made of a conductive material and is arranged radially outside of the moveable support ring 250. The location of the shield ring 260 helps to control voltage of the moveable support ring 250 and to block coupling to the ring 290 (to help maintain high voltage). In some examples, the shield ring 260 may be integrated with the baseplate 210 as will be described further below.

According to some embodiments, the shield ring 260 has an inverted T”-shaped cross-section, an annular body 262, a radially inwardly projecting portion 264 and a radially outwardly projecting portion 266. Lower surfaces of the radially inwardly projecting portion 264 and the radially outwardly projecting portion 266 are arranged directly adjacent to an upper portion of the annular projecting portion 214 of the baseplate 210. The shield ring 260 further includes an upwardly projecting portion 267 extending vertically from a radially outer edge of an upper surface of the annular body 262. A cavity 268 is aligned with the cavity 215 to allow an actuator 192 to move the lift pin 292 reciprocally therein.

As shown in FIGS. 2A-2B, the top cover ring 270 is located above the top moveable ring 240, the shield ring 260 and the ring 280 and has an upper surface that is directly exposed to plasma. In some examples, the top cover ring 270 includes an annular body 272, a first stepped portion 274 and a second stepped portion 276. The first stepped portion 274 is arranged above the upwardly projecting portion 267 of the shield ring 260. The second stepped portion 276 is received by the annular recess 244 of the top moveable ring 240. The second stepped portion 276 covers radially outer edges of the top moveable ring 240 and the moveable support ring 250. In other examples, the top cover ring 270 may include additional steps, fewer steps or no steps. In some examples, the top cover ring 270 has a rectangular cross-section.

The ring 280 is located radially outside of the shield ring 260, the annular projecting portion 214 of the baseplate 210, and a supporting plate 285. The ring 280 includes an annular body 282 and a projection 284 extending radially inwardly from a portion of a radially inner surface of the annular body 282. The annular body 282 includes an annular recess 288 that is arranged on an upper and radially inner edge of the annular body 282. The annular body 282 includes a projecting portion 286 extending radially outwardly from an upper edge of the annular body 282. The ring 290 is located radially outside of the ring 280 below the projecting portion 286. In some embodiments, top cover ring 270 may be made of quartz and ring 280 may be made of quartz or ceramic. .

As can be seen in FIGS. 2A and 2B, an actuator 192 biases the lift pin 292 to adjust a height of the lift pin 292. The lift pin 292 biases the moveable support ring 250 to lift the top moveable ring 240 relative to an upper surface of the substrate 222. Adjusting the geometric height of the top moveable ring 240 compensates for wear due to exposure to plasma. In some examples, the top moveable ring 240, the moveable support ring 250, the shield ring 260 and the ring 290 are made of conductive material. The ring 230, the cover ring 270 and the ring 280 are made of non-conductive material.

The arrangement shown in FIGS. 2A and 2B maintains relatively uniform capacitive coupling with the baseplate 210 and/or the shield ring 260 as the top moveable ring 240 and the moveable support ring 250 move from the lowest position to the various raised positions. In some examples, greater than or equal to 70%, 80%, or 90% of vertically-oriented side portions of a radially outer side surface of moveable support ring 250 are located within a predetermined coupling gap of the shield ring 260 in the various height positions of the top moveable ring 240 and the moveable support ring 250. In the example in FIGS. 2A and 2B, 100% of the vertically-oriented side portions of the radially outer side surface of moveable support ring 250 are located within the predetermined coupling gap of the shield ring 260 in the various height positions of the top moveable ring 240 and the moveable supporting ring 250.

In some examples, the predetermined coupling gap is greater than zero and less than or equal to 30 mils, 20 mils or 10 mils. As used herein, 1 mil = 1/1000 inch. The predetermined coupling gap is sufficiently large to allow relative movement of the moveable rings with sufficient room for expansion of the ring and/or adjacent surfaces due to heating during plasma processing. The predetermined coupling gap should also be small enough to provide sufficient capacitive coupling to adjacent rings or the baseplate to maintain the RF voltage on the top edge ring as the position of the ring is raised due to wear on the top edge ring.

In some examples, greater than or equal to 50%, 60%, or 70% of vertically-oriented portions of a radially inner side surface of moveable support ring 250 are located within a predetermined coupling gap of the baseplate 210 in the various height positions of the top moveable ring 240 and the moveable support ring 250. In some examples, capacitive coupling of vertical side portions of the baseplate 210, the moveable support ring 250 and the shield ring 260 remain constant for all vertical positions of moveable support ring 250.

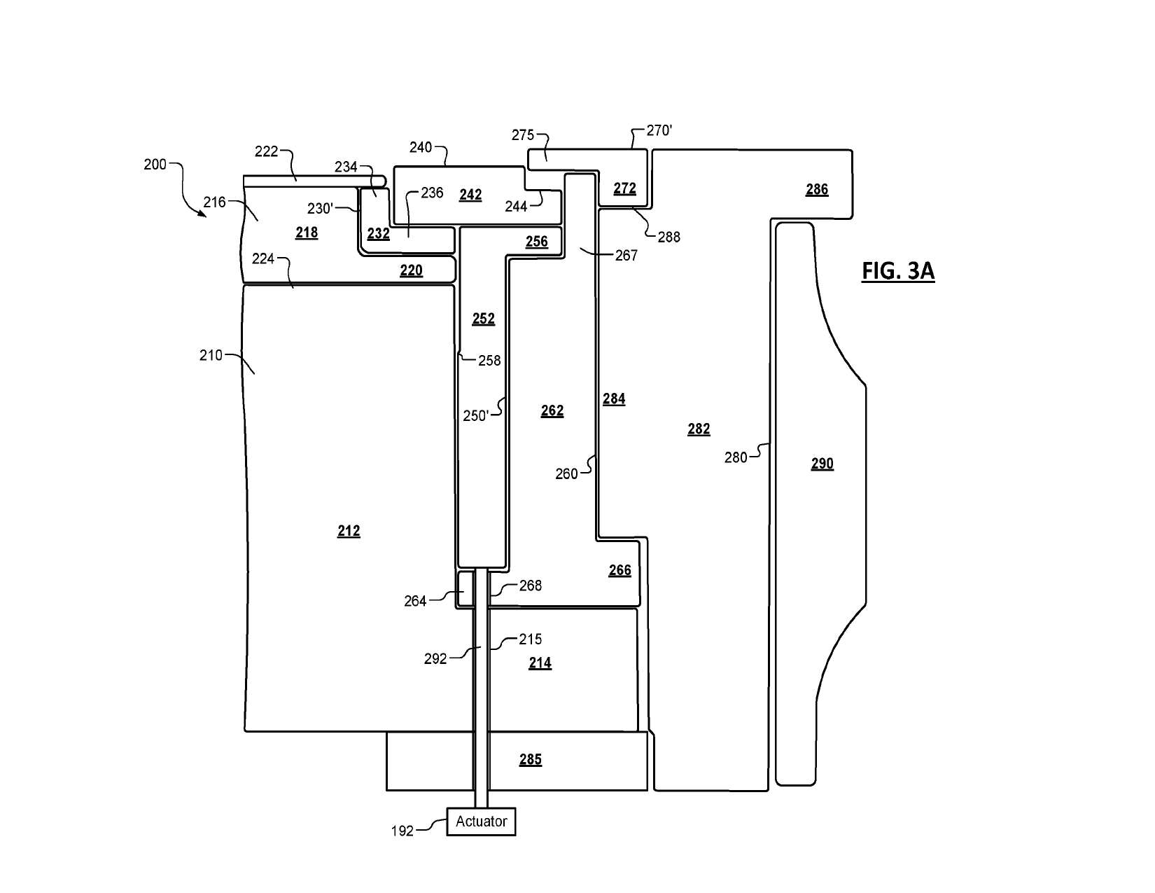

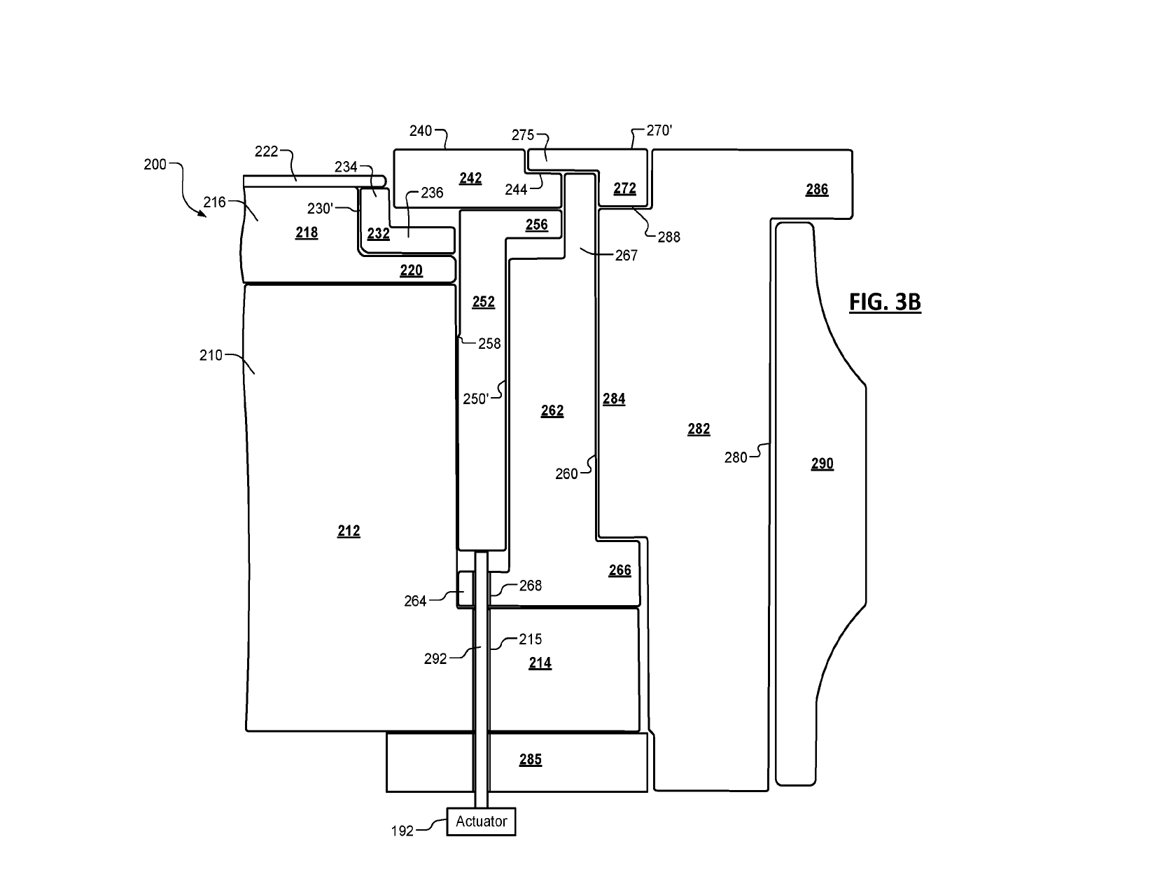

Referring now to FIGS. 3A and 3B, the ring 230, the moveable support ring 250 and the cover ring 270 can have other cross-sectional shapes. In FIG. 3A, a moveable support ring 250’ includes the annular body 252. In some examples, the moveable support ring 250’ has an “L”-shaped cross-section. The horizontal portion 236 of the ring 230’ extends to a radially inner surface of the moveable support ring 250’. A top cover ring 270’ includes a stepped portion 275 extending radially inwardly from the annular body 272 and defining an annular recess to receive the projecting portion 267 of the shield ring 260 and a radially outer surface of the top moveable ring 240. In FIG. 3B, the lift pin 292 biases the moveable support ring 250 to adjust a height of the top moveable ring 240.

Referring now to FIGS. 4A and 4B, an edge ring system 400 according some embodiments of the present disclosure is shown. The RF voltage on a top stationary ring 440 that is directly exposed to plasma is varied by adjusting a height of the moveable ring 450 located below the top stationary ring 440.

In FIG. 4A, the edge ring system 400, according to some embodiments, further includes the ring 430, the shield ring 260, a cover ring 470, the ring 280 and the ring 290 that are stationary. The ring 430 has an annular body and is arranged below a radially outer edge of the substrate 222, directly below a radially inner edge of the top stationary ring 440, directly above the annular projecting portion 220 of the heating layer 216, and between the heating layer 216 and a radially inner edge of the moveable ring 450. In some examples, the ring 430 has a rectangular cross section.

The top stationary ring 440 includes an upper surface that is exposed directly to the plasma. The top stationary ring 440 is arranged partially below a radially outer edge of the substrate 222 and extends radially outwardly past a radially outer edge of the substrate and rises above the substrate 222. The top stationary ring 440 is located partially below the cover ring 470 and above the moveable ring 450 and the shield ring 260. The top stationary ring 440 includes an annular body 442 having a radially inner portion 444, an upwardly sloped portion 445, a planar portion 447 and an annular recessed portion 448 located on an upper and radially outer surface thereof. An upper surface of the top stationary ring 440 is directly exposed to plasma. The slope of the sloped portion 445 allows for even/uniform erosion across the surface to help maintain a stationary thickness across the ring (as compared to right angle designs).

The moveable ring 450 is located below the top stationary ring 440 and between a radially inner surface of the shield ring 260 and a radially outer side surface of the baseplate 210. The moveable ring 450 has an annular body 452. In some examples, the moveable ring 450 has a “T”-shaped cross-section, a radially inwardly projecting portion 454 and a radially outwardly projecting portion 456. In some examples, a radially inner and upper surface 455 of the radially inwardly projecting portion 454 may be sloped in a manner generally parallel to the sloped portion 445 of the top stationary ring 440.

The cover ring 470 is located above the top stationary ring 440, the shield ring 260 and the ring 280 and has an upper surface that is directly exposed to plasma. The cover ring 470 includes an annular body 472, a first stepped portion 474 and a second stepped portion 476. The first stepped portion 474 is arranged above the upwardly projecting portion 467 of the shield ring 260. The second stepped portion 476 is received by the annular recessed portion 448 of the top stationary ring 440.

As can be seen in FIGS. 4A and 4B, the actuator 192 biases the lift pin 292 to adjust a height of the lift pin 292 and the moveable ring 450 to vary capacitive coupling which varies the RF voltage on the top stationary ring 440. Varying the RF voltage compensates for wear of the top stationary ring 440 due to plasma exposure without changing the geometric height of the top stationary ring 440, which reduces non-uniformity. In some examples, the top stationary ring 440, the shield ring 260, the ring 290 and the moveable ring 450 are made of a conductive material. The ring 430, the cover ring 470 and the ring 280 are made of a non-conductive material.

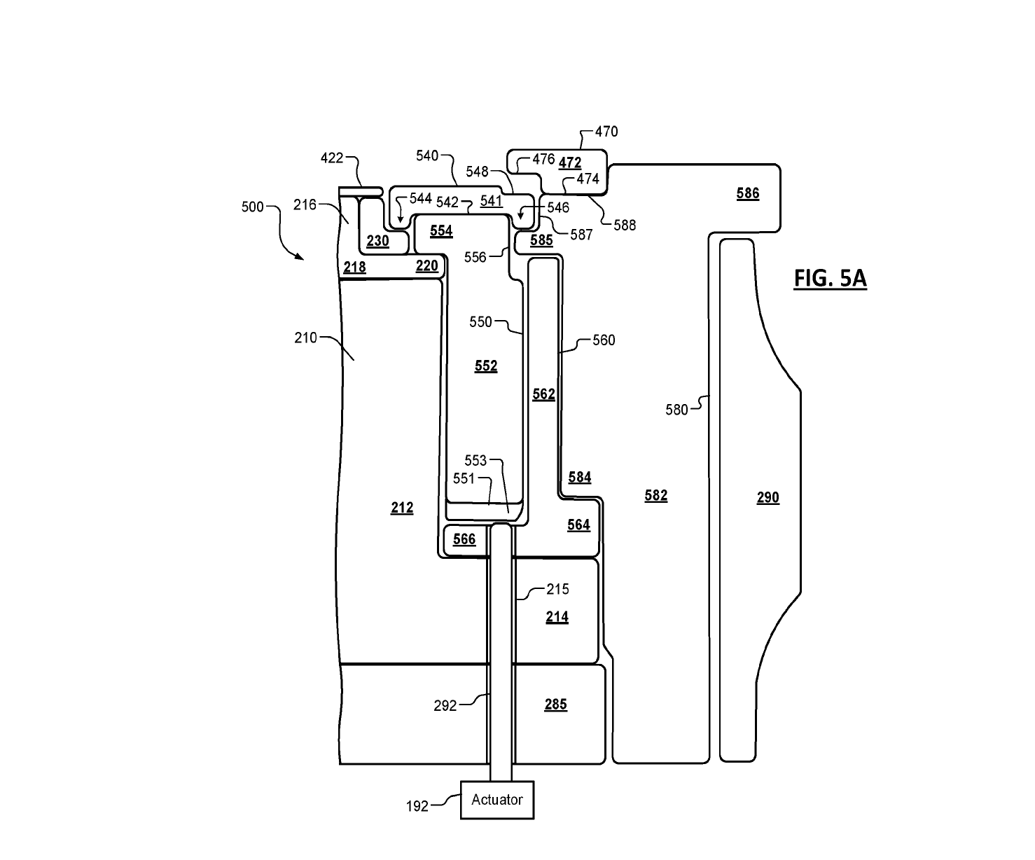

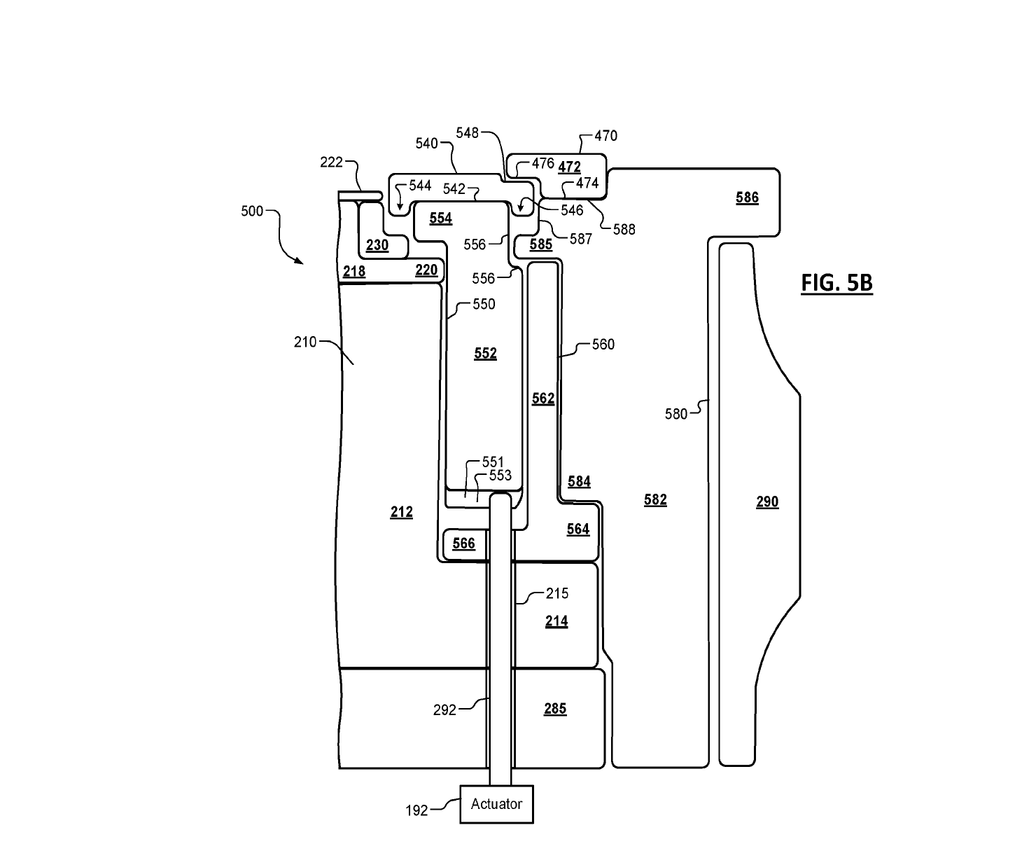

Referring now to FIGS. 5A and 5B, another example of an edge ring system 500 is shown to include a top moveable ring 540, a moveable support ring 550 and a shield ring 560. The top moveable ring 540 is directly exposed to plasma during processing. The top moveable ring 540 rests on the moveable support ring 550. The actuator 192 biases the lift pin 292 into a lower surface of the moveable support ring 550 to adjust a position of the top moveable ring 540 relative to the substrate 422.

The top moveable ring 540 includes an annular body 541. In some examples, the top moveable ring 540 includes a ring centering portion 542 to center the top moveable ring 540 on the moveable support ring 550. In some examples, the ring centering portion 542 may include a cavity formed on a lower surface thereof. In some examples, the cavity has a width sufficient to receive an upper portion of the moveable support ring 250. As can be appreciated, the edge ring systems described herein may include the ring centering portion 542. Downwardly directed projections 544 and 546 of the top moveable ring 540 are arranged at radially inner and outer locations of the annular body 541 on opposite sides of the cavity. An annular recess 548 may be arranged on an upper and radially outer portion of the annular body 541.

In some examples, a lower portion of the top moveable ring 540 includes a ring centering portion 551 to center the moveable support ring 550 relative to the baseplate 210. As can be appreciated, all of the edge ring systems described herein may include the ring centering portion 551. In some examples, the ring centering portion 551 includes a cavity 553 having an inner surface that includes a portion that is sloped linearly or non-linearly (e.g. curved) to bias the moveable support ring 550 into position as it is seated on the lift pin 292. In some examples, the surface of the cavity includes opposing surfaces that provide a centering effect. In some examples, the surface of the cavity has a “V”-shape, a cone shape, a combination of straight and curved shapes or other types of surfaces that provide a centering effect.

The shield ring 560 includes an annular body 562 that partially surrounds the moveable support ring 550. A lower portion of the annular body 562 includes a radially outwardly projecting leg 564 and a radially inwardly projecting leg 566.

A ring 580 is arranged radially outside of the top moveable ring 540, the moveable support ring 550 and the shield ring 560. The ring 580 includes an annular body 582, a first projection 584 extending radially inwardly from a middle portion of a radially inner surface of the ring 580. A projection 585 extends radially inwardly from an upper portion of a radially inner surface of the ring 580. The projection 585 is located below the downwardly projecting leg 546. An annular recess 587 is arranged on the radially inner surface above the projection 585. A projection 586 projects radially outwardly from the upper surface of the ring. An annular recess 588 is arranged on an upper surface of the ring 580. In some examples, the cover ring 470 rests on the annular recess 588. A ring 590 is arranged radially outside of the ring 580 and may be made of a conductive material.

In FIG. 5B, the top moveable ring 540 and the moveable support ring 550 are shown in a raised position. The actuator 192 biases the lift pin 292 into the ring centering portion 551 on the lower surface of the moveable support ring 550 to lift and center the moveable support ring 550, which lifts the top moveable ring 540.

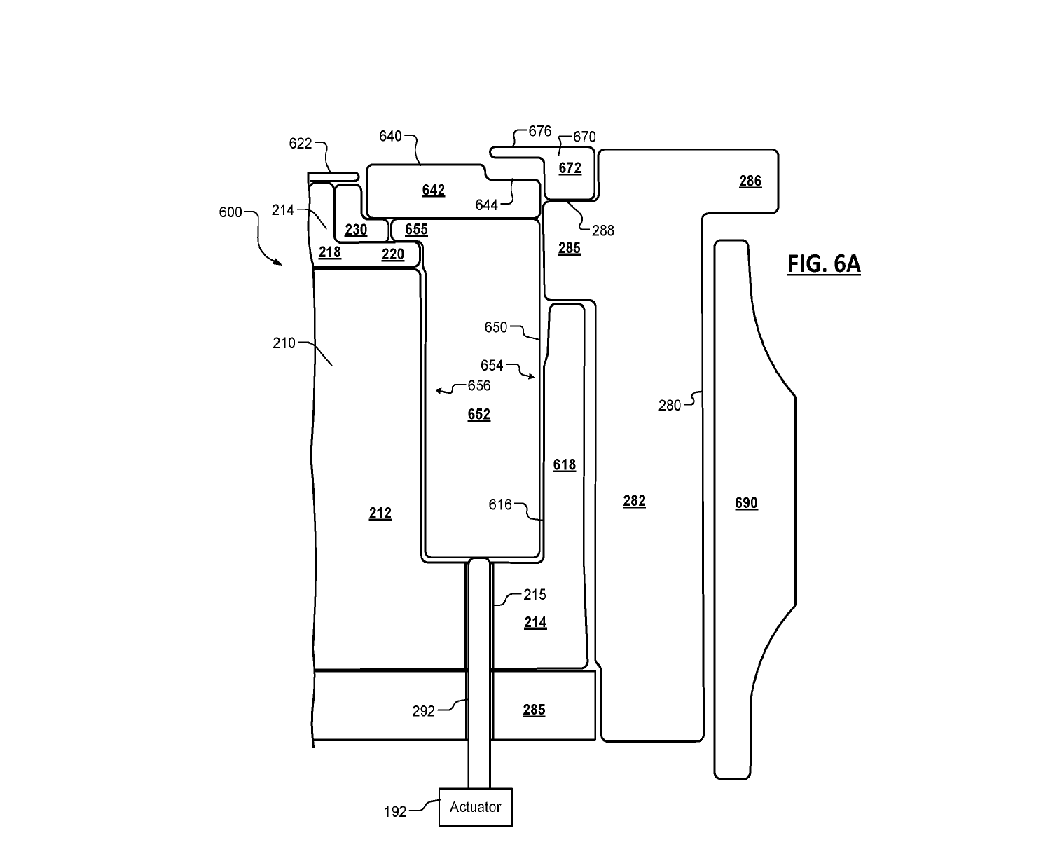

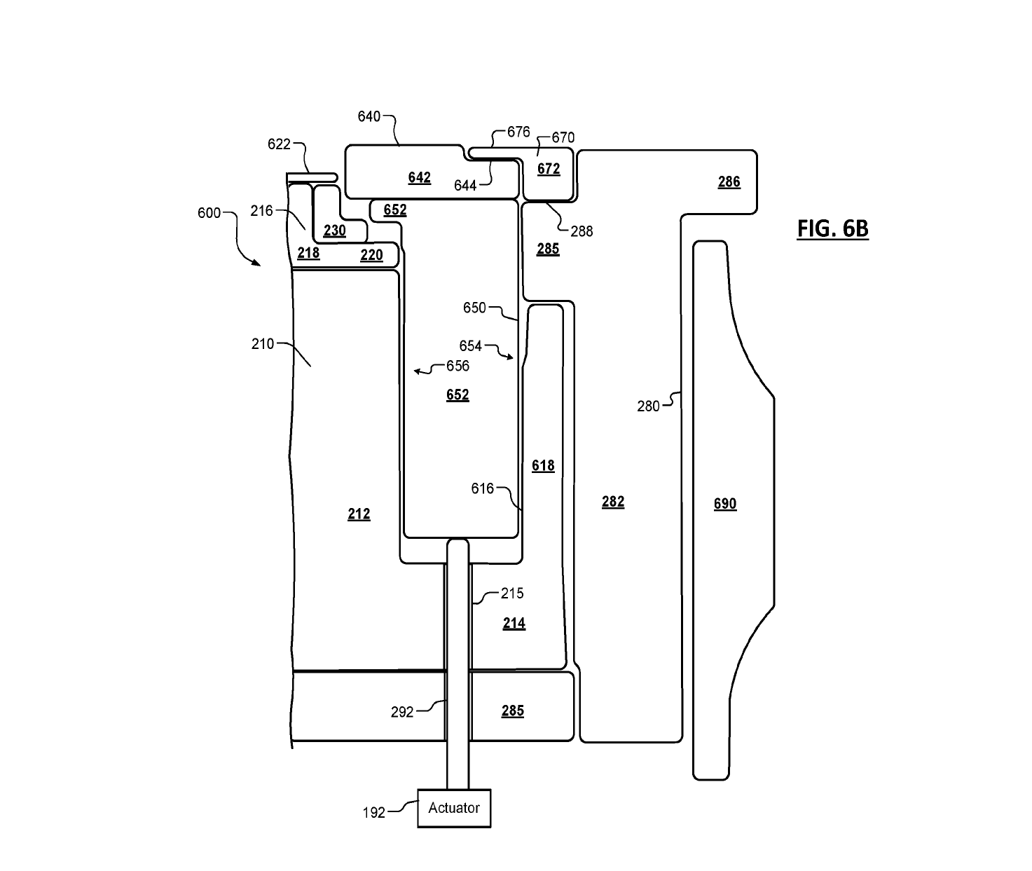

Referring now to FIG. 6A and 6B, another example of an edge ring system 600 is shown and includes a shield ring that is integrated with the baseplate 210. A top moveable ring 640 includes an upper surface that is directly exposed to plasma. The top moveable ring 640 includes an annular body 642. An upper and radially outer surface of the top moveable ring 640 includes an annular recess 644. In some examples, the annular body 642 has a rectangular cross-section.

A moveable support ring 650 is arranged below the top moveable ring 640. The moveable support ring 650 includes an annular body 652, a radially outer surface 654, and a radially inner surface 656. In some examples, the moveable support ring 650 has an “L”-shaped cross-section and includes a projecting portion 655 extending radially inwardly from an upper portion of the radially inner surface 656.

A cover ring 670 is stationary and includes an annular body 672 and a projection 676 extending radially inwardly from an upper surface of the annular body 672. When the top moveable ring 640 is raised (as shown in FIG. 6B), the projection 676 of the cover ring 670 extends into the annular recess 644. According to some embodiments, the baseplate 210, the top moveable ring 640, the moveable support ring 650 and the ring 690 are conductive and the cover ring 670 and the ring 680 are non-conductive.

In the preceding embodiments, some of the edge rings are made of a conductive material or a conductive or non-conductive material with a conductive coating. As used herein, conductive refers to materials or coatings with a resistivity of less than or equal to 10⁴ Ωcm. For example, doped silicon has a resistivity of 0.05 Ωcm, silicon carbide has a resistivity of 1-300 Ωcm and metals such as aluminum and copper have a resistivity of ≈ 10⁻⁸ Ωcm. In some examples, the edge rings of the present disclosure are made of non-conductive material or a conductive or non-conductive material with a non-conductive coating. As used herein, nonconductive refers to materials/coatings with a resistivity of greater than 10⁴ Ωcm.

The conductive rings can be made of one or more base materials, one or more plating layers, and/or one or more coatings. Non-limiting examples of base materials include silicon, silicon carbide, titanium, graphite, quartz, and/or ceramic. Non-limiting examples of plating layers include aluminum plating. Non-limiting examples of coatings include perfluoroalkoxy (PFA), atomic layer deposition (ALD) aluminum oxide (Al₂O₃), ALD yttrium oxide or yttria (Y₂O₃), and/or anodized coatings. For example, the conductive materials may include anodized titanium, silicon with a PFA coating, doped silicon, silicon with aluminum plating and an anodized coating, silicon with ALD aluminum oxide, silicon with an ALD yttria coating, silicon carbide, graphite with a PFA coating, graphite with aluminum plating and an anodized coating, graphite with an ALD aluminum oxide coating, graphite with an ALD yttria coating, or other suitable materials. Non-limiting examples of non-conductive materials include quartz and ceramic. In the preceding embodiments, one or more of the rings may be formed by one or more structures in radial, axial or other directions.

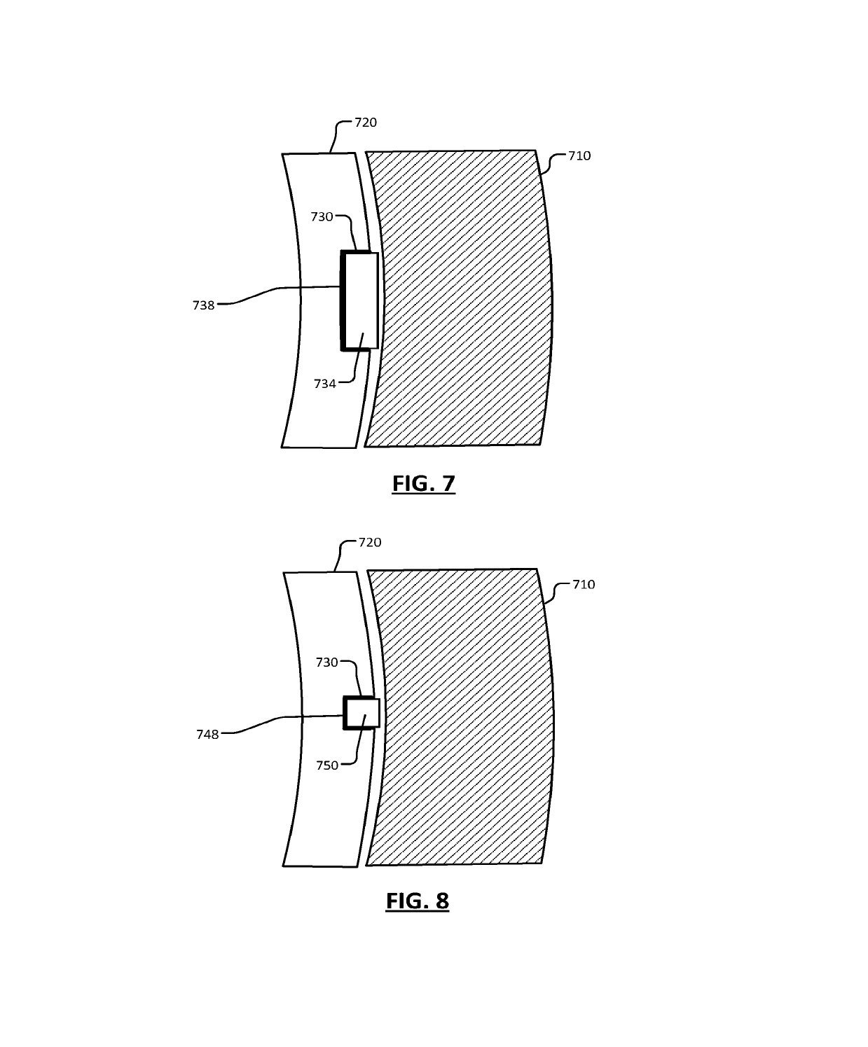

Referring now to FIGS. 7-9B, various ways of limiting movement, controlling spacing and/or horizontal centering one ring relative to another structure such as a ring or the baseplate of the edge ring systems described herein are shown. In FIG. 7, a structure 710 such as a ring, baseplate or other structure in the processing chamber is located adjacent to a surface of a ring 720. FIGS. 7-9B show various ways for limiting movement of the structure 710 relative to the ring 720 are shown.

In FIG. 7, the ring 720 includes a slot 738 located on a radially outer surface thereof. The slot 738 extends radially inwardly into the radially outer surface of the ring 720. A shim 734 is arranged in the slot 738. In some examples, adhesive 730 is used to retain the shim 734 in the slot 738. In some examples, the shim 734 has rectangular plan, radial and side cross-sections, although other shapes can be used. In some examples, the shim 734 has a thickness in a radial direction that is greater than or equal to a depth of the slot 738. In some examples, the shim 734 extends radially outwardly from the ring 720 to a distance sufficient to limit movement (given the number of shims that are used).

In FIG. 8, the ring 720 includes a slot 748 located on a radially outer surface thereof. The slot 748 extends radially inwardly. A pin 750 is arranged in the slot 748. In some examples, adhesive 730 is used to retain the pin 750 in the slot 748. In some examples, the pin 750 has cylindrical shape, although other shapes can be used. In some examples, the pin 750 has a height in a radial direction that is greater than or equal to a depth of the slot 748. In some examples, the pin 750 extends radially from the ring 720 to a distance sufficient to limit movement (given the number of pins that are used). In some examples, the pin 750 extends radially outwardly from the ring 720 to a distance sufficient to limit movement (given the number of shims that are used).

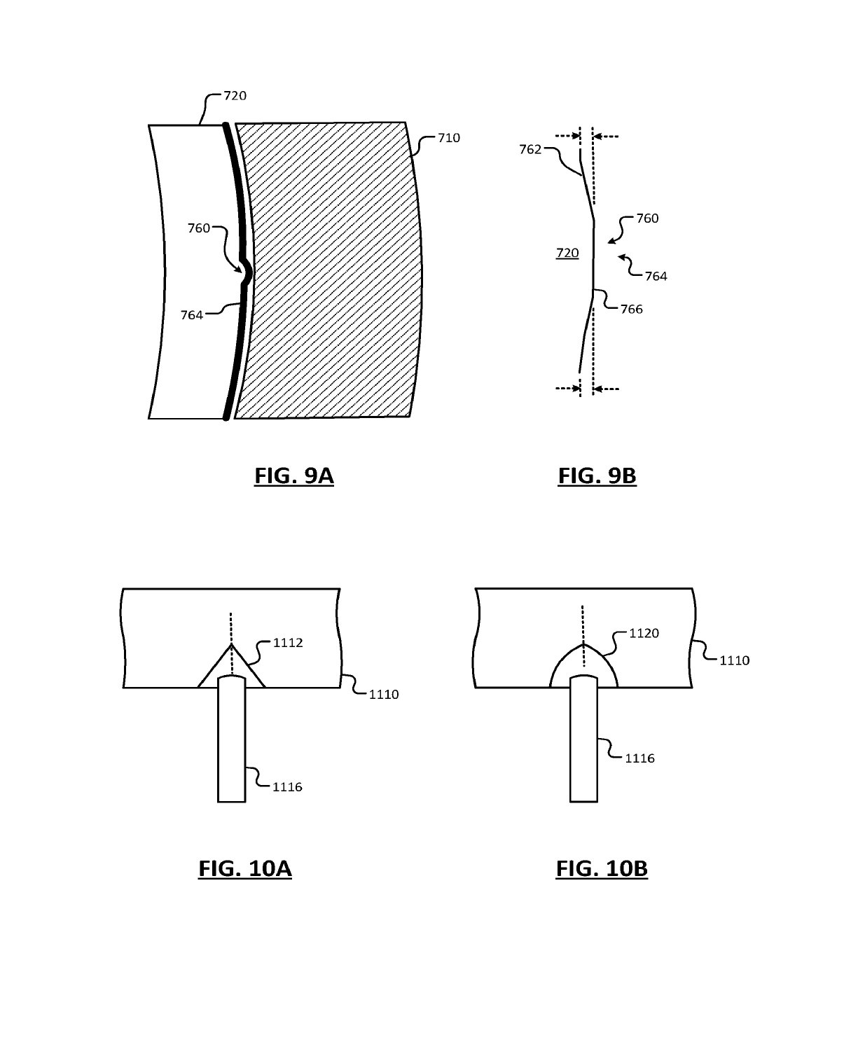

In FIGS. 9A and 9B, the ring 720 includes a projection 760 formed on a radially outer surface thereof. In some examples, the projection 760 extends in a vertical direction partially or fully along the vertical thickness of the radial outer surface. In FIG. 9B, the projection 760 includes a flat surface 766 extending from a radially outer surface 762 of the ring 720, which is easier to machine and to inspect dimensions as compared to arcuate profiles. In some examples, the edge ring is initially formed slightly wider without the projections 760 and then a radially outer surface is machined or removed in areas between adjacent projections to form the projections 760. In other examples, the projections 760 include arcuate or convex profiles in plan view to reduce surface area in contact with the radially inner facing surface of the top edge ring and reduce friction when performing height adjustment or replacing the top edge ring without breaking vacuum.

In some examples, the projections 760 are coated with a coating material 764. In some examples, the coating material 764 is relatively conformal and is made of an insulating material. In some examples, the coating is selected from a group consisting of polytetrafluoroethylene (PTFE), perfluoroalkoxy polymer (PFA), or aluminum oxide, yttrium oxide, or yttrium fluoride deposited using atomic layer deposition. The coating material 764 has an insulating function that prevents short circuits and reduces erosion. The coating material 764 also ensures a minimum gap between the ring 720 and the structure 710 to prevent short circuits. In some examples, the projection 760 extends radially outwardly from a radially outer surface of the ring 720 to a distance sufficient to limit movement (given the number of projections that are used).

In some examples, the ring 720 includes 3 to 8 spacers (shims or projections) arranged with uniform spacing (e.g. 120⁰ spacing for 3, 72⁰ spacing for 5, 45⁰ spacing for 8 (or 360⁰/N)) around an outer periphery of the ring 720. As can be appreciated, the spacers are not generally configured to completely constrain relative movement of upper and lower rings. The gap helps reduce binding during height adjustment and/or replacement. Therefore, some relative movement is still desirable and undesirable movement (which may alter the effective coupling capacitance) may still occur with 3 shims. In some examples, the ring 720 includes 5 spacers arranged around an outer periphery of the ring 720 to further constrain movement. Depending upon the particular configuration, additional spacers such as 6, 7 or 8 provide diminishing returns with respect to controlling the effective capacitance and increase cost.

While the spacers (e.g. shims, projections or projections) are shown arranged on an outer surface of the ring 720, the spacers can be arranged on an inner surface of the ring 720 and/or one or both of the inner surfaces of the structure 710. In addition, the spacers and/or insulating coating can be arranged on any of the preceding examples (e.g. in FIGS. 1 to 6B) on one or both of the radially facing surfaces of an edge ring and an adjacent structure.

In some examples, the spacers extend in a radially outward direction in a range from 50μm to 250μm from a radially outer surface of the edge ring.

Referring now to FIGS. 10A and 10B, additional examples of horizontal ring spacing features are shown. In FIG. 10A, a ring portion 1110 includes a ring spacing feature 1112 located on a lower surface thereof. The ring spacing feature 1112 includes opposing side walls that are mirrored about a center line. Portions of the sidewalls slope inwardly from opposite directions at an inner acute angle with respect to a plane transverse to a direction that a lift pin 1116 moves reciprocally. In some examples, the ring spacing feature 1112 includes a portion having a “V” shape in one plane as shown, two orthogonal planes or more planes pivoting around the center dotted line. In other examples, the ring spacing feature 1112 includes a portion having a cone shape.

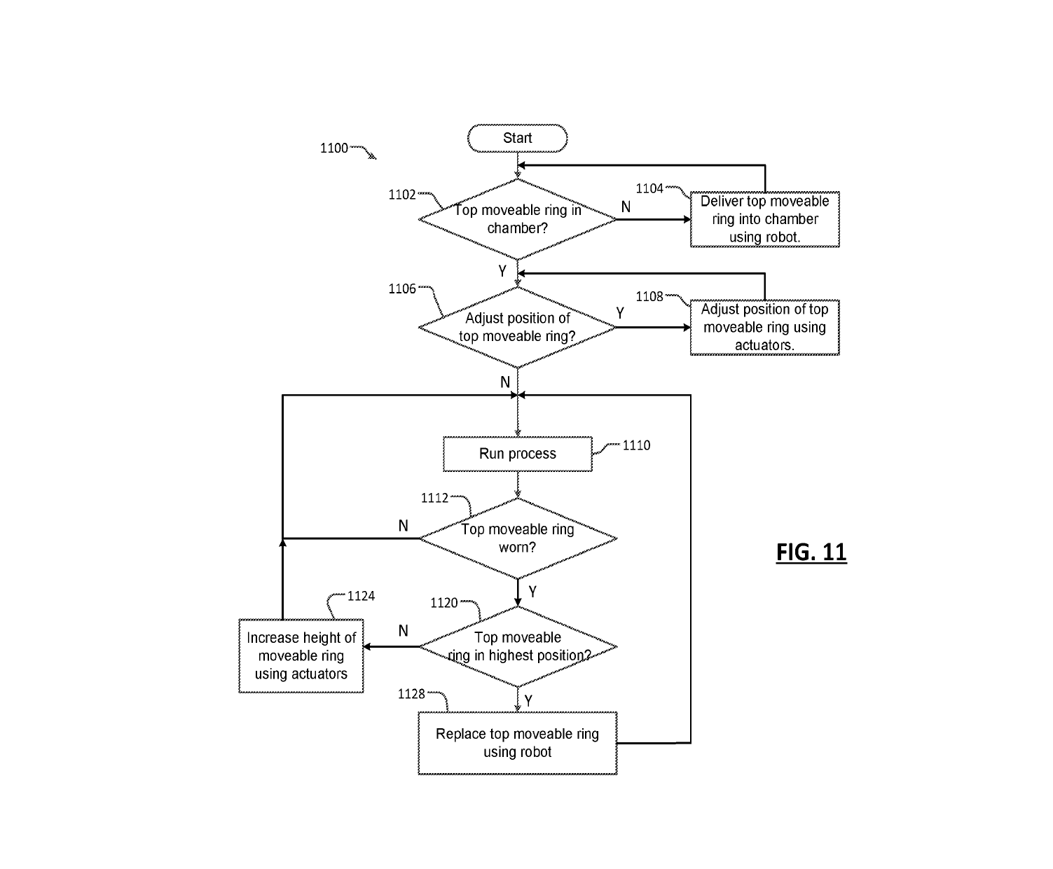

While planar sidewalls are shown, the sidewalls can be planar, partially planar and partially curved, and/or fully curved with varying profiles. As shown in FIG. 11B, a ring portion 1110 includes a ring spacing feature 1120 located on a lower surface thereof. The ring spacing feature 1120 includes opposing side walls that are curved and that are mirrored about a center line.

Referring now to FIG. 11, a method 1100 for adjusting a height of the top moveable ring is shown. In some embodiments, the top moveable ring can be delivered and removed from the processing chamber though a port in the processing chamber without breaking vacuum. In other words, the top moveable edge ring has a diameter less than a width of the port. Once delivered, a height of the top moveable edge ring can be increased over time to compensate for wear caused by exposure to plasma without breaking vacuum. As a result, the processing chamber can be operated for longer periods without opening the processing chamber, which increased throughput and reduces cost.

The method 1100 includes determining whether the top moveable edge ring is in the processing chamber at 1102. If 1102 is false, the method delivers the top moveable ring to the processing chamber at 1104. For example, the system controller 180 causes the robot 190 to deliver the top moveable ring to the processing chamber. If 1102 is true, the method determines whether the position of the top moveable ring needs to be adjusted. For example, one or more sensors may be used to detect a position, height or tilt of the top moveable ring. One or more of the actuators 192 may be used to adjust the position, height or tilt of the top moveable ring relative to an upper surface of the substrate. If 1106 is true, the position of the top moveable ring is adjusted at 1108.

At 1110, the processing chamber processes one or more substrates. At 1112, the method determines whether the top moveable ring is worn. If 1112 is false, the method returns to 1110. If 1112 is true and the top moveable ring is worn, the method determines whether the top moveable ring is in a predetermined position such as a highest position suitable for plasma processing of substrates at 1120. If 1120 is false, the top moveable ring is raised at 1124 and the method continues at 1110. If 1120 is true, the system controller causes the robot to replace the top moveable ring. In some examples, the steps 1106 and 1108 are omitted.

The determination of whether the top moveable edge ring is worn can be made using one or more methods. In certain embodiments, the top moveable edge ring is raised after a predetermined period of exposure to plasma, a predetermined number of substrates are processed, and/or other criteria. In other examples, the sensors 196 are used to sense a height of an upper surface of the top moveable ring.

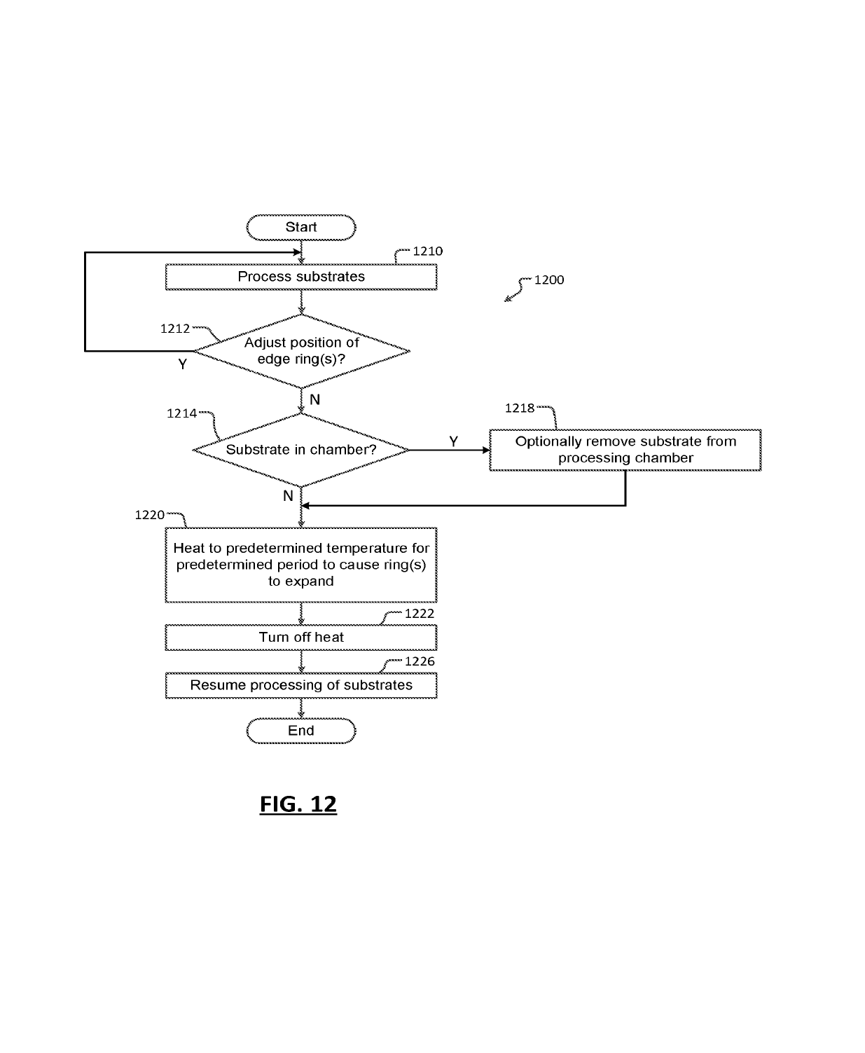

Referring now to FIG. 12, a method 1200 for heating one or more edge rings to reposition or center the edge rings can be used. As the rings, baseplate or other components are heated periodically, on an event basis or using other criteria, the rings, baseplate or other components expand radially outwardly. The radial outward movement can be used directly or indirectly to center or otherwise horizontally position the top moveable ring or other rings.

At 1210, substrates are processed in the processing chamber. At 1212, the method determines whether it is time to adjust a position of the rings or other components. If 1212 is true, the method returns to 1210. If 1212 is false, the method may optionally determine whether a substrate is in the processing chamber at 1214. If 1214 is true, the method may optionally remove the substrate at 1812. For example, the substrate may be removed if the desired heating temperature exceeds a thermal budget for the substrate.

At 1220, if 1214 is false, the heating layer (or other heater in the substrate support or other component) is heated to a predetermined temperature to cause the rings, baseplate or other components to expand and center one or more rings. The rings, baseplate or other components expand radially outwardly. The radial outward movement can be used to center or otherwise position the top moveable ring or other rings in the edge ring system. After the predetermined period, the heater is turned off at 1222 and processing of substrates can resume at 1226.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” As used herein, the term “about” means +/- 10% of a given value and/or +/- 5% of a given percentage.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An edge ring comprising:
an annular body;
a first recess defined in a lower surface of the annular body by a first and second projections extending vertically downwards along inner and outer diameters of the annular body; and
a second recess defined in a radially outer upper portion of the annular body,
wherein the edge ring is configured to move along a vertical direction relative to a substrate support when the lower surface of the edge ring is biased by a support ring arranged under the edge ring.

2. The edge ring of claim 1 wherein the first recess has a greater radial width than the second recess.

3. The edge ring of claim 1 wherein the first projection has a greater radial width than the second projection.

4. The edge ring of claim 1 wherein a radially inner diameter of the second recess is less than an inner diameter of the second projection.

5. The edge ring of claim 1 wherein a sum of heights of the first and second recesses is less than a height of the edge ring.

6. The edge ring of claim 1 wherein the first recess is configured to receive an upper surface of the support ring arranged under the edge ring.

7. The edge ring of claim 1 wherein the support ring is biased by a lift pin passing through a hole formed in a shield ring arranged around the support ring.

8. A shield ring comprising:
a vertical portion of an annular body having a cross-section of an inverted letter T; and
a horizontal portion of the annular body comprising a first portion extending radially inward from a lower end of the vertical portion and a second portion extending radially outwards from the lower end of the of the vertical portion,
wherein the first portion comprises a through hole located closer to an inner diameter of the vertical portion than an inner diameter of the first portion.

9. The shield ring of claim 8 wherein the first portion has a greater radial width than the second portion.

10. The shield ring of claim 8 wherein the first portion has a smaller height than the second portion.

11. The shield ring of claim 8 wherein the first portion is arranged to support a support ring that is arranged radially inwards from the vertical portion and is configured to receive a lift pin passing through the through hole formed in the first portion of the shield ring.

12. The shield ring of claim 11 wherein the support ring is configured to move along a vertical direction relative to a substrate support when a lower end of the support ring is biased by the lift pin.

13. A support ring comprising:
a vertical portion of an annular body; and
a horizontal portion of the annular body comprising a first portion extending radially inward from an upper end of the vertical portion,
wherein the support ring is configured to move along a vertical direction relative to a substrate support when a lower end of the vertical portion of the support ring is biased by a lift pin, and
wherein the horizontal portion is configured to mate with a recess in a lower surface of an edge ring arranged above the support ring.

14. The support ring of claim 13 wherein the horizontal portion has a smaller length than the vertical portion.

15. The support ring of claim 13 wherein the support ring is biased by the lift pin passing through a hole formed in a shield ring arranged around the support ring.

16. The support ring of claim 13 wherein the support ring is configured to move the edge ring along the vertical direction relative to the substrate support when the substrate support is biased by the lift pin.

17. The support ring of claim 13, wherein the horizontal portion of the annular body comprising a second portion extending radially outward from the upper end of the vertical portion.

18. The support ring of claim 17 wherein the first portion has a smaller radial width than the second portion.

19. The support ring of claim 17 wherein the horizontal portion has a smaller length than the vertical portion.

20. The support ring of claim 17 wherein the first and second portions have the same height.
